(19) United States
(12) Patent Application Publication
(10) Pub. No.: US 2009/0000653 A1
(43) Pub. Date: Jan. 1, 2009

(54) Solar power harvester with reflective border

(76) Inventors: Oliver J. Edwards, Ocoee, FL (US); Robert J. Horstmeyer, Palo Alto, CA (US)

Correspondence Address: Tue Nguyen, 496 Olive Ave., Fremont, CA, 94539, US

(21) Appl. No.: 11/824,176

(22) Filed: Jun. 29, 2007

(51) Int. Cl. H01L 31/042

(52) U.S. Cl. 136/244

(57) ABSTRACT

A solar energy harvester comprises: a planar solar harvester panel serving to absorb sunlight and convert it to useful power such as electricity and/or heat; a planar north (in the northern hemisphere) wall which is specularly reflective on its south side, running east-west and positioned adjacent the north end of the harvester panel. The reflective north wall may be considered to create a second, equal, virtual harvester panel to convert additional energy, or alternately to create a virtual sun to illuminate the harvester panel from the north. The solar energy harvester effectively doubles the output of useful power of a prior art solar harvester panel alone.

### FIELD OF INVENTION

The present invention relates to solar power collectors; and more particularly, it relates to enhancement of solar irradiation on a prior art planar solar collector.

### BACKGROUND OF THE INVENTION

Systems for harvesting solar irradiance, of the type with which the present invention is concerned, have application in remote areas where electricity or other utilities are not readily available. However, persons skilled in the art will readily appreciate that the present invention is more broadly directed to a solar energy conversion system, whether the useful energy is in the form of electricity or heat, and irrespective of its ultimate use. Even though the invention has such broader application, it will be disclosed in the context of a source of electrical power which is useful in dwellings and office buildings.

In the past, the most widely employed solar energy converters for solar power harvesting have employed a number of photovoltaic cells mounted to a fixed, planar frame; this is sometimes referred to as a “flat panel” or “one sun” construction. The flat panel was positioned in a well-known manner to enhance the collection of useful solar energy. It is known that if solar energy falls perpendicularly onto the surface of a solar conversion cell, the energy conversion is at a maximum. The attitude and elevation of a solar flat panel in a fixed position for a given location on earth will provide a known maximum conversion of solar energy over the solar day throughout the year—that is, the number of generated watt-hours per day.

However, the number of photovoltaic cells required on a fixed flat panel for a usable power station, considering the various positions of the sun throughout the year, is so large that the system has been prohibitively expensive for conventional commercial use. Performance of this flat panel has been enhanced by providing a motor drive to point the panel at the sun through its diurnal travel. Enhancing the energy harvesting of one-sun collectors was accomplished by mounting the cell array on a tracking device. However, this required the use of a heavy frame and support structures to provide adequate wind resistance. Typically expensive mounting or base structures were required with tracking structures. This further increased the cost of fabricating, installing and maintaining such systems. Exposure to the environment resulted in corrosion, the most frequent cause of system failure.

This has been further enhanced by development of successive generations of more-efficient solar cells: presently typically 15%-40% conversion of sunlight into electricity is possible.

It is widely believed that solar power can be made cost-effective only by concentrating the sun: use of optical means to reduce the quantity of photovoltaic material needed. An important improvement has been made to decrease the cost of the photovoltaic material by concentrating the sunlight, by a linear parabolic trough in the north-south direction which is driven to track the direction of the east-west motion of the sun. This is most often used for concentrating the solar energy to heat a working fluid to drive a power generator.

Numerous methods for tracking the sun with a single-aperture concentrator such as a parabolic dish or trough have been taught; numerous others have addressed the use of co-tracking or group-deformable subapertures.

Perhaps the most important market for solar power conversion would utilize the flat roofs of large commercial buildings: these numerous large areas are generally empty and unused, are conveniently located in urban areas, and have investor-owners ready to purchase this capability when it is economically rewarding.

In all cases the commercial practicality of these successive innovations has been critically limited by the adverse disparity between the value of the solar-generated electrical power versus the amortized aggregated cost of the concentrator structure, the drive apparatus, and the photovoltaic cells themselves. Typically the time for return of the investment has exceeded the projected life of the apparatus, making their value more political than economic.

Thus, the most important aspect of a solar power station is its cost effectiveness: that is, the consideration of the total costs of acquisition, delivery, installation, maintenance, fuel, life expectancy, and the like—versus the market value of the utilities it would replace.

When all the actual costs are accounted, typically the time to return the investment from the value of utilities presently saved (e.g., for San Francisco) ranges from 30 years for a “one-sun” photovoltaic roof-cover to between 40 and 150 years for a state of the art two-axis tracking parabolic dish concentrator.

Solar power harvesters are known to suffer from a number of disadvantages:

(a) Planar stationary collectors which are horizontal have an effective solar intercept area equal to the physical area times the sine of the altitude of the sun. Thus in San Francisco (38° latitude) the noon sun irradiates the collector with 0.79 suns; at 9 AM and 3 PM the solar irradiance is approximately 0.5 sun.

(b) Horizontal single-axis collectors such as parabolic troughs track the sun through its hourly motion. In San Francisco, the irradiance of solar-trough “farms” is thus latitude-limited to 0.79 suns.

(c) A dual-axis tracking solar collector, including the ±23.26° change in elevation as the sun moves through its seasons, can collect one-sun irradiation all day, but at the high investment and maintenance cost of mast-mounted and motorized plates of cells or small concentrators the size of a double garage door. Such a concentrated physical stress at the base under high wind loading requires a specially constructed or strengthened roof.

Accordingly, several objects and advantages of the present invention are:

(a) to provide an improved solar power harvester which can produce up to 100% gain in solar irradiance; that is: up to two suns on a given collector area.

(b) to produce an improved solar harvester which can harvest the same useful power as the present art, but with as little as half the area of required collector footprint.

(c) to provide an improved solar power harvester which does not have moving parts.

(d) to provide a solar power harvester which can return a cash value equal to its total ownership cost within a small fraction of its lifetime.

Other features and advantages of the present invention will be apparent to persons skilled in the art from the following detailed description of a preferred embodiment accompanied by the attached drawings.

### SUMMARY

In accordance with the present invention, a solar irradiation power harvester comprises a prior art planar solar energy harvester panel, and a reflective north wall. The prior art solar energy harvester panel may be a sheet of coplanar harvester cells, or may be a planar array of effectively parabolic trough harvesters, with the useful power output being in the form of photovoltaic and/or thermal power harvest.

The north wall is generally perpendicular or near-perpendicular to the earth, is adjacent the north end of the harvester, and serves to create a virtual second harvester panel north of the physical harvester panel. Alternately it may be seen as creating a virtual sun to add to the direct sunlight on the harvester panel.

### BRIEF DESCRIPTION OF THE DRAWINGS

In the drawings, closely related figures have the same number.

FIG. 1 shows an eastward view of a horizontal harvester panel at noon and 38° N latitude (52° solar elevation).

FIG. 2 shows the same horizontal harvester panel as FIG. 1, with the addition of a north mirror.

FIG. 3 shows an eastward view of a horizontal harvester panel at 38° N latitude noon, a contiguous reflective north wall at various tilts from vertical, and the resultant solid angle of captured sunlight.

FIG. 4 shows a combined harvester panel and north mirror, for three times of day.

FIG. 5 shows an eastward view of a horizontal harvester panel at 38° N latitude, with a horizontal harvester panel.

FIG. 6 shows an eastward view of a horizontal harvester panel at 38° N latitude, with a harvester panel mounted on a south-sloped roof.

FIG. 7 shows an assembly of the taught solar power harvester systems, mounted in array on a flat roof top viewed from a southwest perspective.

### DRAWINGS—REFERENCE NUMERALS

| | |
|---|---|
| 10 | planar solar harvester |
| 12 | noon solar rays incident on harvester |
| 12R | noon solar rays incident on north wall |
| 14 | deleted |
| 16 | reflective north wall |
| 18 | virtual solar harvester |
| 20 | 9 AM solar rays incident on harvester |
| 20R | 9 AM solar rays incident on north wall |
| 22 | 3 PM solar rays incident on harvester |
| 22R | 3 PM solar rays incident on north wall |
| 24 | tracking concentrating trough |
| 26 | power converter |
| 28 | flat-roof building |
| E | Elevation angle of sun |
| R | roof pitch angle |
| L | latitude angle |
| W | physical length of harvester panel |
| H | physical upward width of refledtive wall |

### DETAILED DESCRIPTION OF THE INVENTION

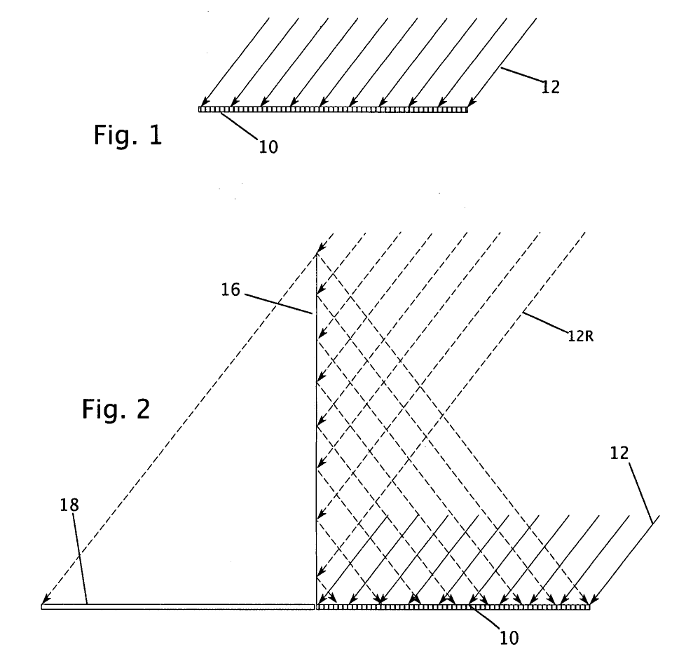

Referring first to FIG. 1, reference numeral 10 refers to a planar solar harvester. This might be of any form which harvest sunlight and converts it to useful power. This useful power might take the forms of heat and/or photovoltaic (PV) electricity. Typical examples of a planar solar harvester include (a) non-tracking: for example a sheet of contiguous PV cells or cell modules; or (b) tracking in one dimension to follow the sun: for example an array of parallel north-south oriented parabolic troughs which track the sun in an east-west direction. The plane of the harvester 10 may horizontal, or it might be sloped for some desirable purpose, such as positioning on a sloped roof.

Sunlight irradiates the harvester 10, as indicted by the sun rays 12. At noon and at the equinox of the year these are sloped from the vertical at an angle equal to the local latitude, and herein are illustrated at the latitude of San Francisco: 38° N.

At the equator, the rays 12 would be vertical; the irradiance at noon would be approximately 1000 watt per meter squared, which we will herein refer to as “one sun”. By inspection of FIG. 1, the irradiance on the panel is proportional to sine of the solar elevation angle: equal to 0.79 suns in San Francisco.

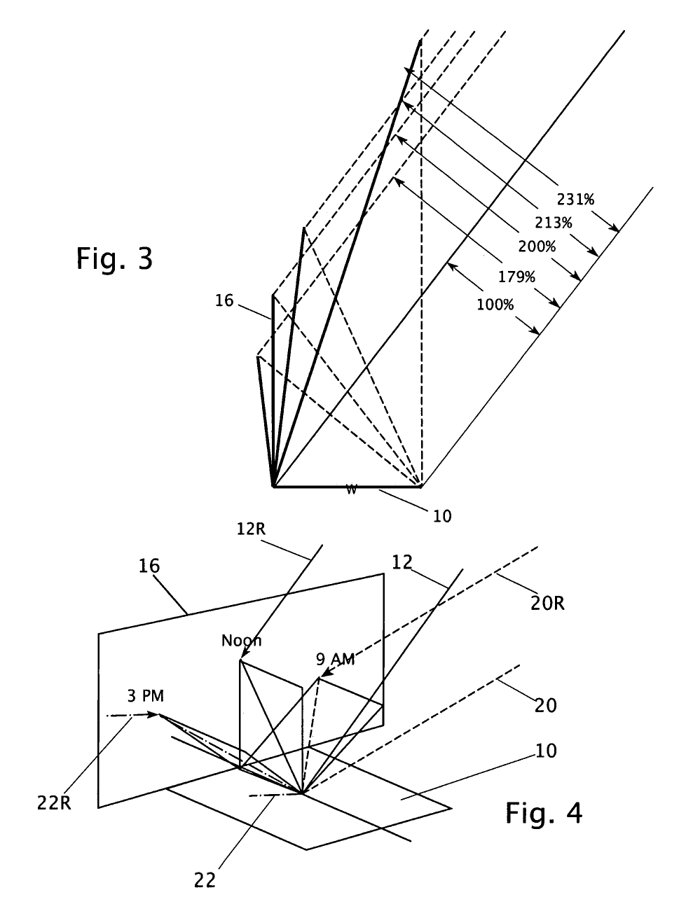

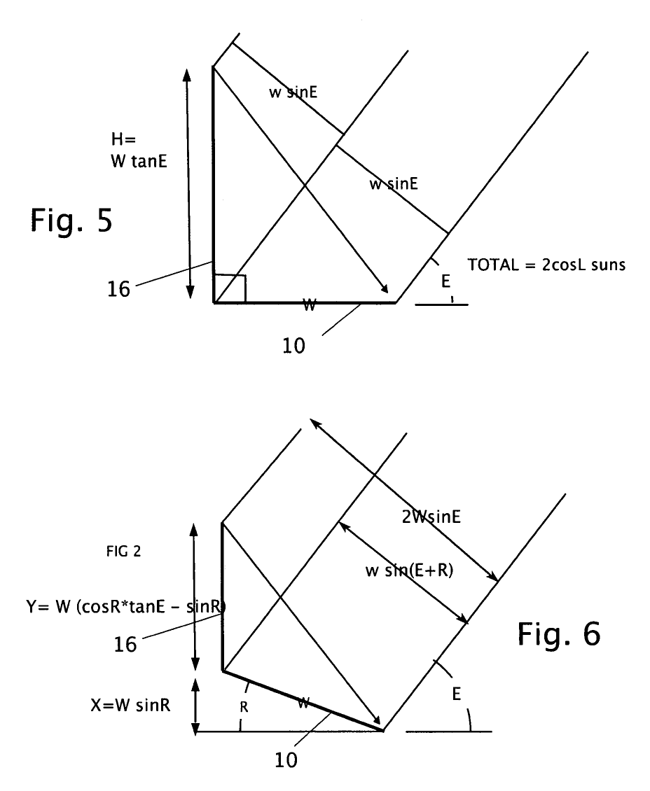

In FIG. 2 a reflective wall 16 is added to the north end of the harvester panel 10. For the sake of illustration the north wall is shown as vertical, although the elevation angle of the wall may be selected from over a range of angles for optimization in a particular situation, as discussed below.

As illustrated the effect of this addition is reflection of additional sunlight onto the harvester panel 10. The height H of the reflective north wall 16 may be usefully adjusted up to a height at which the uppermost reflected rays will miss intersecting with the south edge of the harvester panel. For a vertical wall at noon, at solar equinox, in San Francisco, this would correspond to a height of 1.28 meters per meter of panel width W in the north-south direction. That is: for this vertical north wall mirror the maximum useful height H is equal to W divided by the tangent of the latitude angle.

The effect of the mirror is to create a virtual harvester panel 18 north of the mirror, for an effective doubling of the power output of the harvester panel 10, ignoring reflection losses. Perhaps a more intuitive way to perceive the benefit is as coming from a virtual sun created by the added reflective north wall 16, illuminating the harvester panel 10 from the north.

The reflective north wall may be vertical as discussed above, or it may be inclined in a north-south direction, as shown in FIG. 3. Here a variety of reflective north walls are shown, with useful height defined by that ray which would just reflect to intersect the south edge of the harvester panel 10. If that amount of sunlight which is intercepted directly by the harvester panel 10 is set at a value of 100%, then setting the vertical reflective wall (bearing the label 16) yields a total solar intercept of 200%. Leaning the reflective wall a bit to the north adds reflected sunlight to yield a total solar intercept of 179%. Additional solar concentration may be added in leaning the wall further to the south, up to the total solar intercept of 231% as shown in FIG. 3; however, the increase in the required size of the reflective wall comes at a significant increase in construction cost and vulnerability to wind damage.

It can be shown that for a vertical extent H of the reflective wall, a tilt angle Ø will maximize the sunlight reflected from a selected solar elevation angle E on to a horizontal panel 10 of north-south extent W, such that

H=W times sine (E+2Ø) divided by cosine (E+Ø),

Where Ø is positive in the southward direction.

While it may be found useful to vary the near-vertical angle of the reflective wall through the year to maximize the additional power harvested by the reflective wall as the sun moves from summer solstice to winter solstice, in a preferred embodiment the reflective north wall will be vertical, and have a maximum useful height equal to the north-south width W of a horizontal planar harvester panel times the cotangent of the (local latitude minus 23.26°) to optimally utilize the noon sun at summer solstice.

The width of the vertical reflective wall runs east-west, and must have an E-W extension sufficient to reflect the sun throughout the desired length of the day when solar power is to be harvested. This issue is qualitatively illustrated in FIG. 4, with incident sunlight rays for 9 AM labeled 20, for noon labeled 12, and for 3 PM labeled 22. A ray 20R parallel to ray 20 first strikes the reflective wall. Similarly, offset rays 12R and 22R first strike the reflective wall. All rays are absorbed at the same spot on the harvester panel 10. The planes within which the rays travel are sketched in as perspective rectangles. The width of north wall required to reflect both the 9 AM and later the 3 PM virtual suns onto a given point on the harvester panel is typically greater than the distance of that point from the north wall; this becomes less cost-significant as the east-west dimension of the harvester panel is extended for effective use of a large collector footprint.

In further explication of the reflective north wall, FIG. 5 shows an eastward view of a horizontal harvester panel 10 having a north-south width W, with a vertical reflective north wall 16 matched in height for 38° north latitude. As illustrated, the cylinder of sunlight intersected by the harvester panel 10 has a cross sectional dimension of W times the sine of the solar elevation angle E. Similarly the cylinder of sunlight intersected by the north wall 16 has a cross sectional dimension of W times sine of the solar elevation angle E. Thus, ignoring reflection losses of a few percent, the total irradiance on the panel is twice that for an isolated panel: 2W sin E suns.

FIG. 6 shows the case for a harvester panel 10 installed on a south-facing sloped roof. Here the harvester panel is more nearly perpendicular to the sun rays, and hence more effective an absorber: the cylinder of sunlight intersected by the harvester panel 10 has a cross sectional dimension of W times the sine of (solar elevation E+the roof pitch angle R).

The height of the mirror is correspondingly lowered: the total irradiance heating is the same as for the flat-panel case of FIG. 5: 2W sin E suns.

The elevation angle of the sun at noon is indicated as E in FIG. 6. In a general expression including both the cases of FIGS. 5 and 6, the useful vertical extent of the north reflective wall is equal to W times [cos R times tan E−sin R],

W being the physical north-south length of the solar harvester panel,
R being the pitch angle, if any: i.e., the south-sloping angle of the harvester panel 10 relative to horizontal,
E being the maximum noon elevation angle of the sun relative to horizontal, for which full wall-augmentation is desired.

To illustrate the use of this last formula:

A planar harvester panel which is five meters long in the generally north-south direction is terminated at its north end by a vertical reflective wall, situated at 380 north latitude. The noon elevation E of the sun varies over six months from (latitude+earth's tilt) to (latitude—earth's tilt); that is: 52°+23.26°=75.26° at summer solstice, to 52°−23.26°=28.74° at winter solstice. If the harvester panel is horizontal, the maximum useful height of a vertical mirror in San Francisco varies from 19 meters at summer solstice to 2.7 meters at winter solstice. If the harvester panel is mounted on a roof at a 20° pitch angle then the maximum useful height of the mirror varies from 16 meters at summer solstice to 0.9 meter at winter solstice.

In another illustration: if due to architectural or municipal limitations the height of the reflective wall is limited to five meters, then a vertical reflective north wall is maximally effective only for those days when the maximum solar elevation is 45° or less if the harvester panel is flat, or when the maximum solar elevation is 55.2° or less if the harvester panel is inclined at 20° south.

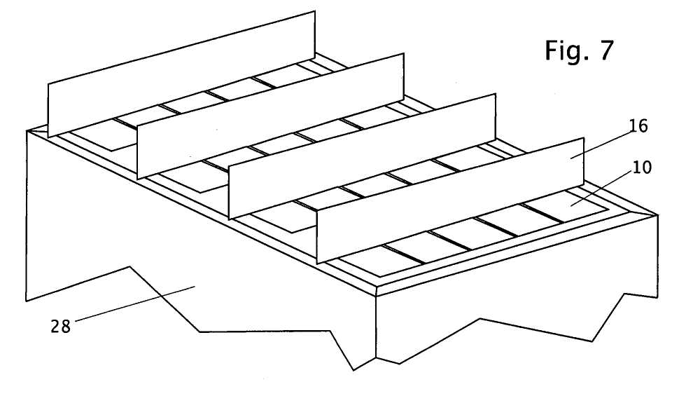

One of the principal opportunities for harvesting of solar energy is from the roofs of large office buildings, commercial stores, and warehouses. Typically these large flat areas have no purpose other than weather exclusion, and their unclaimed area can be made valuable by harvesting solar energy for useful electrical power and/or thermal power. FIG. 7 shows the flat top of a building 28, bearing east-west arrays of contiguous harvester panels 10. Each array has a corresponding reflective north wall 16 to double the irradiance on the panels 10 by “stealing” the sunlight which would fall north of the panel. Typically the north wall 16 will be a continuous east-west sheet, and at the ends a detailed cost analysis is required to define the extent of the wall beyond the outside limits of the array of panels 10. That is to say: the cost of the wall extended beyond the ends of the array is to be traded off against value of the additional energy harvest and the acceptability of roof overhangs in a particular case. Especially in northern climates, the additional roof structure will decrease the heat losses to the environment. Where snow has fallen, the incidence of two suns in the daytime will in most cases lead to a rapid melting and runoff of the snow covering the harvester panel.

This FIG. 7 rooftop might alternately represent a portion of a large field of solar harvesters, such as might be built by a local utility company. In either case the operational virtue of this innovation is that one may approximately halve the number of solar collectors and generate the same power. That is: the cost of the photovoltaic cells, mirrors, modules, or whatever the nature of the harvester panel 10 is halved, at the added cost of erecting a billboard-like reflective wall: typically 5% to 10% of the cost of the harvester panels 10 which it replaces.

The construction of the reflective north wall may be similar to that of a highway billboard: sheets of plywood on a frame, supported by stays against wind pressure. The front is covered with a thin sheet of reflective material, such as thin stainless steel or aluminum. Copious prior art describes methods for preparing an aluminum mirror surface in sheet form for maximizing reflectivity, while ensuring weather resistance.

Alternately it may be made of a lightweight external frame on which is stretched a reflective membrane.

The present invention, in summary, provides a solar power harvesting system whereby the solar irradiance on a planar solar harvester panel is enhanced by a reflective north wall which produces a second, virtual sun irradiating the harvester panel. For the case of a horizontal solar harvester panel and a vertical reflective wall, the irradiance can be approximately doubled. This doubling of the irradiance on the harvester panel comes at the relatively small cost, typically between 5% and 10% of the cost of a second harvester panel to produce the same added power.

This maximizes the economic value of a given amount of roof or field area in approximately halving the quantity of costly solar harvesting panels required to harvest substantially all the sunlight irradiating the area.

Aside from possibly providing energy where none is otherwise available, the economic value of a solar power harvester lies in the market value of the oil, natural gas or coal which its use will displace. The solar power harvester of the present teaching may pay back the cost of its purchase in little more than half the time required by solar harvesting panels of prior teaching.

By use of thin planar stainless steel, aluminum or similar mirror foil stretched across a simple billboard-like or external frame construction, such a reflective north wall may be erected at low cost and have a useful lifetime measured in decades.

All of these advantages reduce the cost of all system components and installation, maximize the solar power harvest for a given available land or roof area, and increase system life and reliability.

Having thus described in detail a preferred embodiment of the invention, persons skilled in the art will be able to modify certain of the structure which has been illustrated and to substitute equivalent elements for those disclosed while continuing to practice the principle of the invention, and it is, therefore, intended that all such modifications and substitutions be covered as they are embraced within the spirit and scope of the appended claims.

We claim:

1. A system comprising
a planar solar energy harvester panel having an east-west width and a north-south length;
and a planar wall reflective on its south side, running substantially east-west, and disposed substantially adjacent the north limit of said solar energy harvester.

2. A system as in claim 1 wherein the reflector is disposed substantially vertical with respect to the surface of the earth.

3. A system as in claim 2, where the useful vertical extent of the reflector is equal to
W*[cos R*tan E−sin R],
W being the physical north-south length of the solar harvester,
R being the pitch angle which is the south-sloping angle of the harvester relative to horizontal,
E being the maximum noon elevation angle of the sun relative to horizontal.

4. A system as in claim 1 wherein the reflector is disposed at an acute angle with respect to the surface of the earth.

5. A system as in claim 4 wherein the planar solar energy harvester panel is substantially horizontal, and the reflector is tilted in a north-south direction at an angle Ø from vertical, Ø being positive in the southward direction, where the useful upward length H of the reflector is equal to H=W [sin(E+2Ø) divided by cos(E+Ø)],
E being the maximum noon elevation angle of the sun for which it is desired that the reflected sunlight pattern on the harvester panel be maximized.

6. A system as in claim 1 wherein the width of the reflector is not less than the width of the solar harvester.

7. A system as in claim 6 wherein the width of the reflector is at least the width of the solar harvester plus twice the difference between the 9 AM and noon positions on the reflector of the sun rays which terminate at the center of the southern edge of the solar harvester.

8. A system as in claim 1 wherein the solar harvester comprises an energy converter served to absorb sunlight.

9. An improvement to a solar harvester, the improvement comprising a planar reflector disposed to generate a virtual image of the sun for providing additional solar irradiance to the solar harvester.

10. An improvement as in claim 9 wherein the reflector is disposed substantially vertical with respect to the ground.

11. An improvement as in claim 10 wherein the useful vertical extent of the reflector is equal to
W*[cos R*tan E−sin R],
W being the physical north-south length of the solar harvester,
R being the pitch angle which is the south-sloping angle of the harvester relative to horizontal,
E being the maximum noon elevation angle of the sun relative to horizontal.

12. An improvement as in claim 9 wherein the reflector forms an acute angle with the horizontal.

13. An improvement as in claim 11 wherein the width of the reflector is not less than the width of the solar harvester.

14. An improvement as in claim 13 wherein the width of the reflector is at least the width of the solar harvester plus twice the difference between the 9 AM and noon positions on the reflector of the sun rays which terminate at the center of the southern edge of the solar harvester.
